(19) United States
(12) Patent Application Publication
(10) Pub. No.: US 2026/0100705 A1
(43) Pub. Date: Apr. 9, 2026

(54) ENCODED DIFFERENTIAL BALANCED PAM-4 DRIVER STRUCTURE

(71) Applicant: QUALCOMM Incorporated, San Diego, CA (US)

(72) Inventors: Chung-Ching LIN, San Diego, CA (US); Hongmei LIAO, San Diego, CA (US); Sethu LAKSHMANAN, San Diego, CA (US)

(21) Appl. No.: 18/907,257

(22) Filed: Oct. 4, 2024

(51) Int. Cl. H03K 19/003; H03K 19/00; H03K 19/0185

(52) U.S. Cl. CPC H03K 19/00361; H03K 19/0013; H03K 19/018528

(57) ABSTRACT

A driver circuit has a logic circuit and a driver subcircuit. The driver subcircuit includes pullup transistors coupled between an output of the driver circuit and a first power rail and pulldown transistors coupled between the output of the driver circuit and a second power rail. The logic circuit includes combinational logic and is configured to turn on a predefined number of transistors during each data transmission interval. The duration of the data transmission interval is configured for an associated data communication channel. The transistors that are turned on may be selected during each data transmission interval based on a value of multibit data to be encoded in signaling state of the data communication channel. The logic circuit may be further configured to turn off transistors in the plurality of transistors that are not selected from the plurality of transistors based on the value of multibit data to be encoded.

### TECHNICAL FIELD

The present disclosure generally relates to driver circuits and, more particularly, to driver circuits implemented in interfaces that support pulse-amplitude modulation.

### BACKGROUND

Electronic device technologies have seen explosive growth over the past several years. For example, growth of cellular and wireless communication technologies has been fueled by better communications, hardware, larger networks, and more reliable protocols. Wireless service providers are now able to offer their customers an ever-expanding array of features and services, and provide users with unprecedented levels of access to information, resources, and communications. To keep pace with these service enhancements, mobile electronic devices (e.g., cellular phones, tablets, laptops, etc.) have become more powerful and complex than ever. Increasingly, chiplets are employed to implement system-on-a-chip (SoC) devices that can accommodate ever increasing complexity. SoCs typically use multiple high-speed bus interfaces for communication of signals between chiplets.

High-speed serial buses offer advantages over parallel communication links when, for example, there is demand for reduced power consumption and smaller footprints in integrated circuit (IC) devices. In a serial interface, data is converted from parallel words to a serial stream of bits using a serializer and is converted back to parallel words at the receiver using a deserializer. A serializer/deserializer (SERDES) may be used to transmit and receive data through a serial communication link. Increasingly, IC devices are expected to support very high data-rate communications. In some examples, the aggregate rate of data communication within an SoC or between chiplets can exceed several terabits per second (Tb/s) with resultant high power consumption and interface complexity. Therefore, there is an ongoing need for new techniques that provide reliable lower-power data transmission for use in high-data rate data communication links.

### SUMMARY

Certain aspects of the disclosure relate to IC devices that include a driver circuit in a communication interface that supports pulse-amplitude modulation. In one aspect, the communication interface includes a serializer circuit, a driver subcircuit and a logic circuit.

In various aspects of the disclosure, a driver circuit has a plurality of transistors and a logic circuit. The plurality of transistors includes pullup transistors that are coupled between an output of the driver circuit and a first power rail and pulldown transistors that are coupled between the output of the driver circuit and a second power rail. The logic circuit may be configured to turn on a predefined number of transistors during each data transmission interval configured for a data communication channel. The transistors that are turned on may be selected during the each data transmission interval from the plurality of transistors based on a value of multibit data to be encoded in signaling state of the data communication channel. The logic circuit may be further configured to turn off transistors in the plurality of transistors that are not selected from the plurality of transistors based on the value of multibit data to be encoded.

In various aspects of the disclosure, a method for transmitting data includes selecting a predefined number of transistors in a driver circuit to be turned on during a data transmission interval based on a value of multibit data to be encoded in signaling state of a data communication channel, turning on the predefined number of transistors during the data transmission interval, the transistors that are turned on being selected from a plurality of transistors that includes pullup transistors coupled between the data communication channel and a first power rail and pulldown transistors coupled between the data communication channel and a second power rail, and turning off transistors in the plurality of transistors that are not selected from the plurality of transistors based on the value of multibit data to be encoded.

In certain aspects, the multibit data is to be encoded using PAM. In one example, PAM-4 modulation is used to encode two-bit elements of the multibit data. Each two-bit element may be configured as a two-bit number having a most significant bit (MSB) and a least significant bit (LSB). The two-bit number may be received in a serial datastream. In one example, three transistors are turned on during each data transmission interval. The three transistors may include three pullup transistors when the multibit data to be encoded has a first value. The three transistors may include two pullup transistors and one pulldown transistors when the multibit data to be encoded has a second value. The three transistors may include one pullup transistors and two pulldown transistors when the multibit data to be encoded has a third value. The three transistors may include three pulldown transistors when the multibit data to be encoded has a fourth value.

In certain aspects, four different signaling states are defined for the data communication channel. In one example, a combination of pullup transistors and pulldown transistors turned on during each data transmission interval produces voltage levels in the data communication channel that correspond to one of the four different signaling states.

In certain aspects, each transistor in the plurality of transistors is configured to contribute a same nominal impedance to an output of the driver circuit when turned on. In certain implementations, differential control signals are used to control pairs of transistors in the plurality of transistors. In certain implementations, the pullup transistors and the pulldown transistors comprise N-type metal-oxide-semiconductor transistors.

### BRIEF DESCRIPTION OF THE DRAWINGS

FIG. 1 examples of systems and components of systems that may be adapted in accordance with certain aspects of the present disclosure.

FIG. 2 illustrates an example of a transmitter circuit that may be adapted in accordance with certain aspects of this disclosure.

FIG. 3 illustrates examples of circuits that may be configured to transmit data over a communication link.

FIG. 4 illustrates an example of a logic subcircuit and a driver subcircuit that may be implemented in a line driver according to certain aspects of this disclosure.

FIG. 5 illustrates different configurations of the driver subcircuit illustrated in FIG. 4 for each signaling state supported by a PAM-4 interface.

FIG. 6 is a flowchart of a method for transmitting data using a driver circuit configured in accordance with certain aspects of this disclosure.

### DETAILED DESCRIPTION

The detailed description set forth below in connection with the appended drawings is intended as a description of various configurations and is not intended to represent the only configurations in which the concepts described herein may be practiced. The detailed description includes specific details for the purpose of providing a thorough understanding of various concepts. However, it will be apparent to those skilled in the art that these concepts may be practiced without these specific details. In some instances, well-known structures and components are shown in block diagram form in order to avoid obscuring such concepts.

Several aspects of the invention will now be presented with reference to various apparatus and methods. These apparatus and methods will be described in the following detailed description and illustrated in the accompanying drawings by various blocks, modules, components, circuits, steps, processes, algorithms, etc. (collectively referred to as “elements”). These elements may be implemented using electronic hardware, computer software, or any combination thereof. Whether such elements are implemented as hardware or software depends upon the particular application and design constraints imposed on the overall system.

Data communication links may be deployed to facilitate communication between IC devices that are mounted on a printed circuit board (PCB) or on a substrate material. Data communication links may be provided to couple functional components and circuits provided within an integrated circuit (IC) device. In one example, a data communication link may be provided in a system-on-a-chip (SoC) or another type of IC device to connect processors with modems and other peripherals. Data communication links may be operated in accordance with industry or proprietary standards or protocols associated with certain functions or types of devices. According to certain aspects of the disclosure, a serial data link may be used to interconnect electronic devices that are subcomponents of an apparatus such as a cellular phone, a smart phone, a session initiation protocol (SIP) phone, a laptop, a notebook, a netbook, a smartbook, a personal digital assistant (PDA), a satellite radio, a global positioning system (GPS) device, a smart home device, intelligent lighting, a multimedia device, a video device, a digital audio player (e.g., MP3 player), a camera, a game console, an entertainment device, a vehicle component, a wearable computing device (e.g., a smart watch, a health or fitness tracker, eyewear, etc.), an appliance, a sensor, a security device, a vending machine, a smart meter, a drone, a multicopter, or any other similar functioning device.

Increased functionality and switching frequencies tend to increase the demand for greater throughput for certain types of communication links. For example, better performing communication links may be required to support processors that are expected to implement increasingly complex functions and/or to process increased volumes of data within reduced timeframes. Examples of processor include central processing units (CPUs), graphical processing units (GPUs), digital signal processors (DSPs), neural processing units (NPUs) among other examples. The throughput of a communication link may be limited by a maximum frequency of signaling specified for the communication link or the maximum practical frequency of signaling. In some systems, pulse-amplitude modulation (PAM) can be used to increase the throughput of a communication link without increasing the nominal maximum signaling frequency specified for the communication link. In one example, the use of four-level pulse-amplitude modulation (PAM-4) can be used to increase data transmission rates without increasing the signaling rate over a communication link. PAM-4 increases the data rate through the use of four signal levels to enable two bits to be transmitted in a single data transmission interval.

Process technology employed to manufacture semiconductor devices, including IC devices is continually improving. Process technology includes the manufacturing methods used to make IC devices and defines transistor size, operating voltages and switching speeds. Features that are constituent elements of circuits in an IC device may be referred as technology nodes and/or process nodes. The terms technology node, process node, process technology may be used to characterize a specific semiconductor manufacturing process and corresponding design rules. Faster and more power-efficient technology nodes are being continuously developed through the use of smaller feature size to produce smaller transistors that enable the manufacture of higher-density ICs.

Certain examples of clock generation circuits are disclosed herein. Certain clock generation circuits are illustrated as being implemented using certain combinations of P-type metal-oxide-semiconductor (PMOS) transistors and N-type metal-oxide-semiconductor (NMOS) transistors. These circuits are provided by way of example only, and it is contemplated that the concepts disclosed herein can be implemented in circuits that use different combinations of NMOS and PMOS transistors or complementary metal-oxide-semiconductor (CMOS) digital circuits. Circuits that include NMOS, PMOS or CMOS transistors are typically coupled to the rails of a power supply. The power supply provides a current that flows from a higher voltage rail to a lower voltage rail. A rail may include some combination of conductors, wires, connectors and other types of interconnect. For the purposes of this description, the higher voltage rail may be referenced as “VDD” or “V_{DD}” and the lower voltage rail may be referred to as Ground. In some implementations, power may be provided to certain circuits through more than two rails.

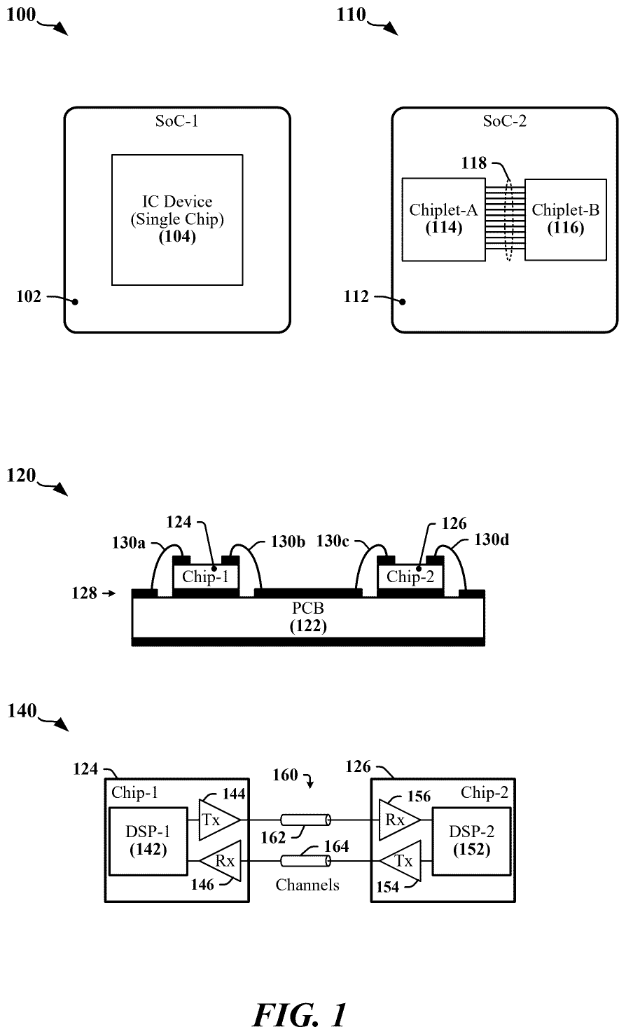

FIG. 1 illustrates examples of systems and components of systems that may be adapted in accordance with certain aspects of the present disclosure. In a first example, substantially all of the circuits and components of a conventional SoC 100 may be provided within a single IC device 104 mounted on a substrate 102. One or more data communication links may enable communication between functional circuits within the IC device 104. One or more data communication links may couple functional circuits within the IC device 104 to other IC devices or external circuits. The IC device 104 may be coupled to external circuits through pins, wires, solder pads or other input/output (I/O) connectors. In order to meet the demand for greater functionality, the size of a typical IC device 104 has increased over time to accommodate the increased complexity circuits within the SoC 100. The increased size and complexity can reduce manufacturing yields and can increase cost. In many applications, yields can be improved by separating functional elements of the single IC device 104 into multiple smaller IC devices, which may be referred to as “chiplets.” SoCs implemented using chiplets can accommodate more complex and larger circuits with reasonable yields. In some instances, yields can be improved by concentrating more advanced and higher cost technology nodes into one group of chiplets, while other chiplets can be manufactured using more conventional technology nodes to support lower-speed or less critical circuits. Chiplet-based SoCs are increasingly used in automotive, complex computational and mobile communication device applications.

An example of a chiplet-based SoC 110 includes two or more chiplets 114, 116 mounted on a substrate 112. In this example, interconnects 118 may be provided to couple the chiplets 114, 116. The interconnects 118 may carry power, control signals and/or may implement one or more data communication links. The chiplets 114, 116 may be further coupled to external circuits through pins, wires solder pads or other I/O connectors. In some implementations, the chiplet-based SoC 110 includes chiplets that are stacked vertically on the substrate 112. Some chiplets can be included in stacks that are deployed across the surface of the substrate 112, while other chiplets may be individually mounted on the surface of the substrate 112. In one example, chiplets may be mounted on the surface of the substrate 112 using solder balls that provide electrical and/or thermal coupling between the substrate 112 and certain chiplets. An interconnect structure may be formed that enables chiplets in a stack of chiplets to communicate with one another, with other chiplets mounted on the substrate 112 and with I/O structures that couple the SoC 110 with other circuits, displays, imaging sensors and other peripherals with an apparatus. The interconnect structure may be used to implement multiple data communication links. In some implementations, an SoC (not illustrated) may include some combination of chiplets that are mounted across a substrate and chiplets that are vertically stacked with respect to the substrate.

The use of stacked chiplets can reduce the areal size of the substrate 130 and increase three-dimensional packing density. The constituent chiplets may provide complex features and high performance within a smaller form-factor operated at lower power specifications. Moreover, each chiplet may define multiple power domains, operate at different frequencies and different chiplets may manage power/frequency modes independently and. In some instances, two or more chiplets may be operated in mutually exclusive power states. Additionally, operating conditions for an SoC depend on the type, number and arrangement of chiplets included on the substrate in addition to the modes of operation defined by applications. It is necessary to consider power usage by all chiplets in the SoC in order to ensure compliance with power budgets assigned for an application or device.

Increasingly, IC devices are expected to support very high data-rate communications. In some examples, the aggregate rate of data communication within an SoC or between chiplets can exceed several terabits per second (Tb/s). Hundreds or thousands of interconnects may be implemented to support such data rates. The communication between the chips requires high-speed, low-power, low-latency links.

FIG. 1 also illustrates an IC device 120 that includes a data communication link 160 that is further illustrated in the associated schematic representation 140. The data communication link 160 is provided between two IC devices 124, 126, labelled as Chip-1 and Chip-2. The IC devices 124, 126 may be mounted on a PCB 122 and connected through traces in a metallization layer 128. In the illustrated example, certain connections are made through the base of the IC devices 124, 126 while other connections, including the data communication link 160 are implemented using bonded wires 130a, 130b, 130c, 130d in what may be referred to as a wireline interface.

In the illustrated examples, the data communication link 160 couples DSPs 142 and 152, which may be provided within respective IC devices 124 and 126. From the perspective of each of the DSPs 142 and 152, the data communication link 160 includes a transmit channel and a receive channel. The first DSP 142 is configured to transmit data over a first channel 162 and to receive data over a second channel 164. The second DSP 152 is configured to receive data over the first channel 162 and to transmit data over the second channel 164. The first IC device 124 includes a transmitter circuit 144 that is coupled to a receiver circuit 156 in the second IC device 126. The second IC device 126 includes a transmitter circuit 154 that is coupled to a receiver circuit 146 in the first IC device 124.

The IC device 120 may be included in an apparatus that includes multiple subcircuits. In one example, the apparatus may be enclosed within a wearable device a portable or wearable processing and/or communication device (each of which being referred to herein as a portable communication device or PCD), sensors, instruments, appliances and other such devices include one or more ICs. These devices may include mobile phones, tablet computers, palmtop computers, portable digital assistants (PDAs), portable game consoles, and other portable electronic devices such as a smartwatch. PCDs commonly contain integrated circuits or SoCs that include numerous components or subsystems designed to work together to deliver functionality to a user. The various SoC subsystems may communicate with each other via one or more intra-chip data buses or similar data communication interconnects. PCDs may have multiple SoCs that communicate with each other via similar inter-chip interconnects. The ICs are typically packaged in an IC package, which may be referred to as a “semiconductor package” or “chip package.” The IC package typically includes a package substrate and one or more IC chips or other electronic modules mounted to the package substrate to provide electrical connectivity to the IC chips. For example, an IC chip in an IC package may be configured as an SoC. The IC chips are electrically coupled to other IC chips and/or to other components in the IC package through electrical coupling to metal lines in the package substrate. The IC chips can also be electrically coupled to other circuits outside the IC package through electrical connections of external metal interconnects (e.g., solder bumps) of the IC package.

The apparatus may include multiple subcircuits. One or more of the subcircuits may include or implement a processor, memory and one or more modems. The subcircuits may include an application processor, display driver, camera interface, audio controller and/or analog-to-digital controllers, for example. The apparatus may include a variety of processing engines, such as CPUs with multiple cores, GPUs, DSPs, NPUs, wireless transceiver units (also referred to as modems), peripherals, display and imaging interfaces, etc. Each of these subsystems and other functional elements can be implemented in an IC device, SoC or using some combination of chiplets, IC devices and/or SoCs.

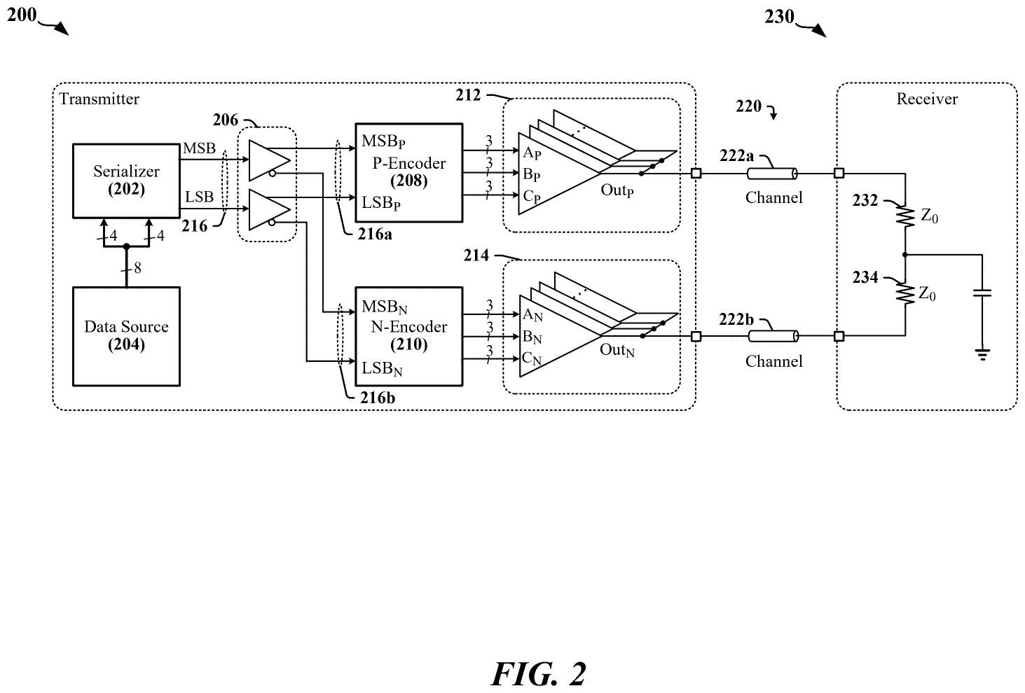

FIG. 2 illustrates an example of a transmitter circuit 200 that may be adapted in accordance with certain aspects of this disclosure. In the illustrated example, the transmitter circuit 200 is implemented as a differential transmitter and is configured to generate a differential data signal for transmission over the data communication link 220. For the purposes of this disclosure, a differential signal comprises a complementary pair of signals that are phase-shifted by 180° with respect to one another. A first signal that is a phase-shifted by 180° with respect to a second signal may be referred to as an inverted version of the second signal. In the illustrated example, the transmitter circuit 200 includes a serializer 202 that can be configured to receive parallel data from a data source 204. The data source 204 may provide data generated by an application, sensor, peripheral or other source of data. In some instances, the data may be generated by a pseudorandom binary sequence (PRBS) generator that may be used for training or calibrating the transmitter circuit 200 or the data communication link 220.

In the illustrated example, the serializer 202 generates a two-bit datastream 216. Two bits of the parallel data are provided during each data transmission interval defined for the data communication link 220. In one example, each data transmission interval corresponds to a cycle of a transmitter clock signal used to control transmission over the data communication link 220. In another example, each data transmission interval corresponds to a half-cycle of the transmitter clock signal used to control transmission over the data communication link 220. In each data transmission interval, one bit of the parallel data is designated as the MSB and the other bit of the parallel data is designated as the LSB. The MSB and LSB form a binary number that can select one of four signaling states for the differential data signal during the corresponding data transmission interval.

The two-bit datastream 216 is provided to a single-ended to differential conversion circuit 206. In the illustrated example, the single-ended to differential conversion circuit 206 includes driver circuits that output differential versions of single-wire signals received at their respective inputs. Non-inverted versions of the MSB and LSB are provided to a first encoder circuit 208 and inverted versions of the MSB and LSB are provided to a second encoder circuit 210. The encoder circuits 208 and 210 generate control signals that are provided to corresponding line driver circuits 212 and 214. Each line driver circuit 212, 214 includes multiple driver segments or subcircuits, which may be referred to herein as driver slices. The control signals that are provided by the encoder circuits 208 and 210 turn on and turn off transistors in one or more driver slices of the corresponding line driver circuits 212 and 214.

The number of driver slices enabled at any time may determine an output characteristic of the line driver circuits 212 and 214. In one example, the number of driver slices enabled for combinations of LSB and MSB values may be selected to match the characteristic impedance of the corresponding channels 222a, 222b. In another example, the number of driver slices enabled for combinations of LSB and MSB values may be selected to obtain a desired or specified impedance for the corresponding line driver circuit 212, 214. In another example, the number of driver slices enabled for combinations of LSB and MSB values may be selected to determine the drive strength of the corresponding line driver circuit 212, 214. In another example, the number of driver slices enabled for combinations of LSB and MSB values may be selected to determine the output voltage of the corresponding line driver circuit 212, 214.

The line driver circuits 212 and 214 drive corresponding channels 222a, 222b of the data communication link 220. The channels 222a, 222b are typically terminated at a receiver 230 using resistive components 232, 234 that provide an impedance that matches the characteristic impedance (Z₀) of the channels 222a, 222b. The line driver circuits 212 and 214 are configured or calibrated to present an impedance that matches the characteristic impedance of the channels 222a, 222b. Each enabled driver slice in the line driver circuits 212 and 214 typically contributes to the impedance presented to the channels 222a, 222b by the line driver circuits 212 and 214.

The architecture of the line driver circuits 212 and 214 is critical in wireline interfaces. The impedance presented by the line driver circuits 212 and 214 can affect the ability of the transmitter circuit 200 to meet timing and voltage specifications defined for the interface. The line driver circuits 212 and 214 must be capable of conforming to modulation specifications regarding voltage levels assigned to signaling states, with signal rise and fall rates that enable a receiving circuit to reliably capture encoded and/or modulated data. Typically, the output impedance of the line driver circuits 212, 214 must be matched to the characteristic impedance for all signaling states in an interface that uses PAM-4 modulation.

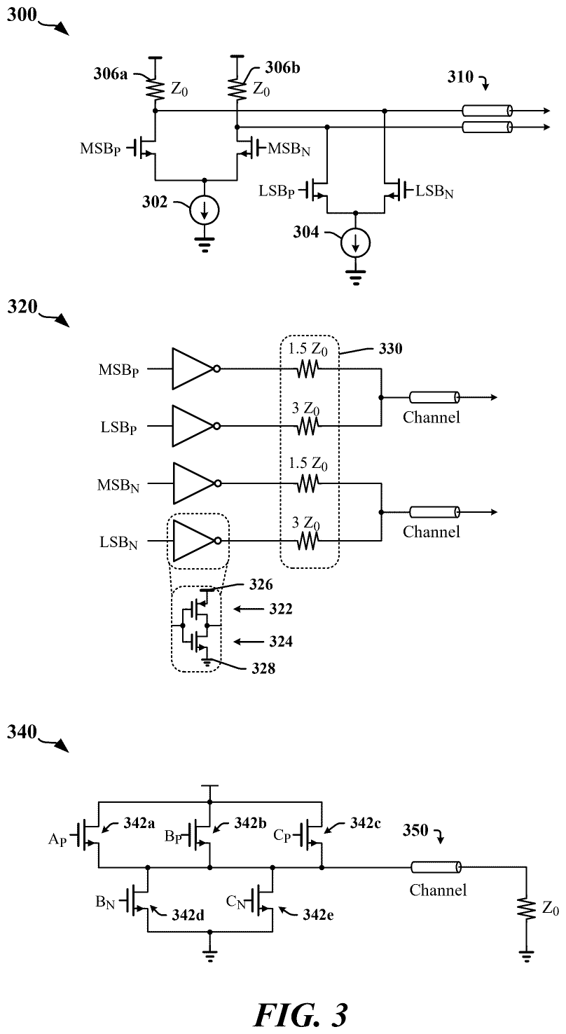

With reference to FIG. 3, some conventional systems use a current mode driver 300 in the transmitter circuit 200. Signaling state of the data communication link 310 is determined by controlling current sources 302, 304 in the current mode driver 300. Impedance matching is accomplished using resistive components 306a, 306b. The use of the current mode driver 300 enables impedance matching to be accomplished with minimal complexity but results in high power consumption due to the constant-on state of the current sources 302, 304. The current mode driver 300 also imposes a minimum additional headroom to maintain the operation of the current sources 302, 304.

Some conventional systems use a first type of voltage mode driver 320 in the transmitter circuit 200, where the first type of voltage mode driver 320 is implemented using a combination of PMOS transistors 322 and NMOS transistors 324. The inclusion of PMOS transistors 322 and NMOS transistors 324 enables controllable voltage swings between power rails 326, 328, while enabling the first type of voltage mode driver 320 to be configured to accommodate deviations in expected operational characteristics that are attributable to variations in process, voltage or temperature (PVT). Certain disadvantages are associated with the inclusion of PMOS transistors 322 and NMOS transistors 324 in the first type of voltage mode driver 320. In one example, a tradeoff is typically required between impedance allocated to the resistors 330 and impedance allocated to the transistors 322, 324. In some instances, it can be difficult to ensure matching of circuits that handle LSB and MSB signals across expected PVT variations. In some instances, it can be difficult to ensure matching of circuits that handle LSB and MSB signals based on variations attributable to physical circuit layout.

In some interfaces, a second type of voltage mode driver 340 is implemented using NMOS transistors 342a-342e, and without including PMOS transistors in the driver circuit. Certain of the disadvantages associated with the inclusion of PMOS transistors 322 and NMOS transistors 324 in the first type of voltage mode driver 320 apply also to the second type of voltage mode driver 340. One advantage of limiting the circuit to NMOS transistors is that the second type of voltage mode driver 340 can operate when supply voltage is less than 0.4V. In the illustrated example, the second type of voltage mode driver 340 does not include resistors for impedance matching purposes, and impedance matching is accomplished by adjusting the configuration of driver slices in the driver circuit. However, impedance matching is difficult and failure can be expected when the signaling state of a PAM-4 signal is in the lower voltage states. Failure may be characterized as degradation in signal quality due to reflections and jitter in the data communication link 350, which can cause loss of data integrity.

Certain aspects of this disclosure relate to a voltage mode driver that can be implemented using NMOS-only driver segments. According to certain aspects, impedance matching can be maintained for all signaling states in PAM-4 interfaces when the disclosed voltage mode driver is used. According to certain aspects, impedance matching is maintained or readily achievable for all expected PVT corners when the disclosed voltage mode driver is implemented. For the purposes of this disclosure, PVT corners represent limits of process, voltage, or temperature and/or combinations thereof. PVT corners may be correlated with limits of operational characteristics of a circuit, including current, voltage, temperature, switching frequency, rise time, fall time, and other characteristics.

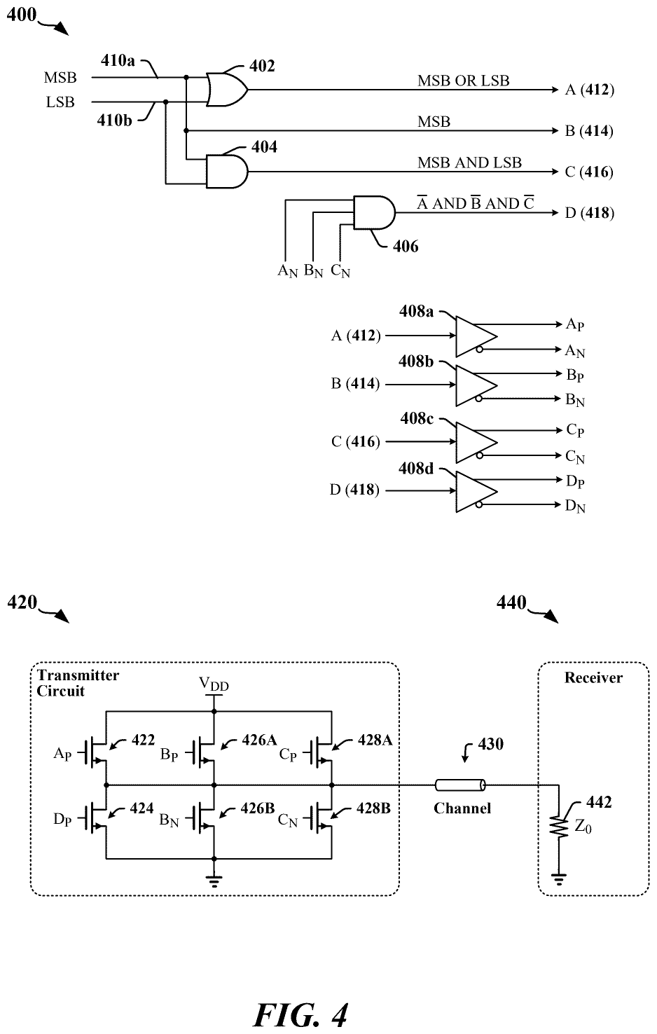

FIG. 4 illustrates an example of a logic subcircuit 400 and a driver subcircuit 420 that may be implemented in a line driver according to certain aspects of this disclosure. The logic subcircuit 400 that may be used to control the driver subcircuit 420 and one or more other driver subcircuits included in the line driver. In some implementations, the driver subcircuit 420 is one of multiple driver segments that are coupled to an output of the line driver. In one example, multiple driver segments can be coupled in parallel such that outputs of the driver segments are configured to drive the same output of the line driver, and such that the gate of each transistor in each driver segment is coupled to the gates of corresponding transistors in the other driver segments. In some instances, the outputs of the driver segments are coupled to a channel 430 that couples the line driver to a receiving device.

The logic subcircuit 400 receives input signals 410a, 410b that represent a sequence of two-bit numbers to be encoded using PAM-4 modulation. The logic subcircuit 400 may receive the sequence of two-bit numbers in serial datastream, such as the two-bit datastream 216 output by the serializer 202 illustrated in FIG. 2. One input signal 410a represents bits in the datastream that are designated as the MSBs of the two-bit numbers and the other input signal 410b represents bits that are designated as the LSBs of the two-bit numbers. The logic subcircuit 400 outputs four control signals 412, 414, 416 and 418 that are used to control transistors 422, 424, 426A, 426B, 428A, 428B in the driver subcircuit 420. In the illustrated example, the transistors 422, 424, 426A, 426B, 428A, 428B are fabricated as NMOS transistors. The logic subcircuit 400 determines which of the transistors 422, 424, 426A, 426B, 428A, 428B are turned on or otherwise enabled for each possible value of the two-bit numbers.

In the illustrated example, the driver subcircuit 420 includes three pullup transistors 422, 426A and 428A, and three pulldown transistors 424, 426B and 428B. Three of the transistors 422, 424, 426A, 426B, 428A, 428B are turned on or otherwise enabled for each possible value of the two-bit numbers, such that the nominal impedance presented to the channel 430 by the driver subcircuit 420 is constant or consistent for all possible values of the two-bit numbers. The nominal impedance presented to the channel 430 by the driver subcircuit 420 or the line driver may be configured or calibrated to match the characteristic impedance of the channel 430. Reflections and jitter can be minimized when the impedance presented to the channel 430 by the receiver circuit 440 also matches the characteristic impedance of the channel 430. In the illustrated example, the receiver circuit 440 includes a terminating resistor 442 that has a value (Z₀) that corresponds to the characteristic impedance of the channel 430.

In the illustrated example, the driver subcircuit 420 may be configured to drive one channel 430 of a differential communication link. A second, typically matching line driver may be provided to drive the complementary channel of the differential communication link.

In the illustrated example, the logic subcircuit 400 includes an OR gate 402 that outputs a first control signal (the A signal 412). The A signal 412 is in a high signaling state when either of the input signals 410a, 410b is in a high signaling state. For the purposes of this disclosure the high signaling state represents a logic ‘1’ state and has a higher voltage level than a low signaling state, which represents a logic ‘0’ state. Pullup transistor 422 is turned on when the A signal 412 is in the high signaling state. The gate of pullup transistor 422 receives a non-inverted version (A_{P}) of the A signal 412. Pullup transistor 422 is turned off when the A signal 412 is in the low signaling state.

Input signal 410a (i.e., the MSB) is passed through the logic subcircuit 400 and provided as a second control signal (the B signal 414). Pullup transistor 426A is turned on and pulldown transistor 426B is turned off when the MSB and the B signal 414 are in the high signaling state. Pullup transistor 426A is turned off and pulldown transistor 426B is turned on when the MSB and the B signal 414 are in the low signaling state. The gate of pullup transistor 426A receives a non-inverted version (B_{P}) of the B signal 414 and the gate of pulldown transistor 426B receives an inverted version (B_{N}) of the B signal 414. Accordingly, only one of the transistors 426A, 426B is turned on during driver operation.

The logic subcircuit 400 further includes an AND gate 404 that outputs a third control signal (the C signal 416). The C signal 416 is in the high signaling state when both of the input signals 410a, 410b are in a high signaling state. Pullup transistor 428A is turned on and pulldown transistor 428B is turned off when the C signal 416 is in the high signaling state. Pullup transistor 428A is turned off and pulldown transistor 428B is turned on when the C signal 416 is in the low signaling state. The gate of pullup transistor 428A receives a non-inverted version (C_{P}) of the C signal 416 and the gate of pulldown transistor 428B receives an inverted version (C_{N}) of the C signal 416. Accordingly, only one of the transistors 428A, 428B is turned on during driver operation.

The logic subcircuit 400 further includes an AND gate 406 that outputs a fourth control signal (the D signal 418). The D signal 418 is in the high signaling state when each of the A signal 412, the B signal 414 and the C signal 416 is in the low signaling state. The D signal 418 is in the low signaling state when any of the A signal 412, the B signal 414 and the C signal 416 is in the high signaling state. Pulldown transistor 424 is turned on when the D signal 418 is in the high signaling state and turned off when the D signal 418 is in the low signaling state. In the illustrated example, the gate of pulldown transistor 424 receives a non-inverted version (D_{P}) of the D signal 418. Pulldown transistor 424 is turned on only when the three pullup transistors 422, 426A and 428A are turned off. When the three pullup transistors 422, 426A and 428A are turned off, the pulldown transistors 426B and 428B are turned on and turning on pulldown transistor 424 provides a third pulldown that can nominally ensure that impedance matching is preserved for the lowest voltage PAM-4 state.

The illustrated logic subcircuit 400 is an example in which three transistors are enabled for any combination of LSB and MSB values. In other implementations, the logic subcircuit 400 may be configured to enable a different number of transistors for any combination of LSB and MSB values. A line driver provided in accordance with certain aspects of this disclosure may include multiple driver slices, where each driver slice has a structure that is substantially similar to the structure of the illustrated driver subcircuit 420. In some implementations, each driver slice may be individually enabled or disabled to obtain a desired drive strength and/or desired output impedance for the line driver. In some implementations, one or more driver slices may be partially enabled or disabled such that one or more of the control transistors 422, 424, 426A, 426B, 428A, 428B can be enabled or disabled to obtain a desired drive strength for one or more combinations of LSB and MSB values. In one example, a line driver can be configured to implement some form of equalization by varying the number of control transistors 422, 424, 426A, 426B, 428A, 428B that are enabled or disabled for different combinations of LSB and MSB values.

In some implementations, the logic subcircuit 400 may be expanded to account for the management of multiple instances of the control transistors 422, 424, 426A, 426B, 428A, 428B and/or multiple instances of the driver subcircuit 420. For example, the AND gate 406 may receive additional inputs that accommodate differences in control signals provided to different driver slices, including when the MSB or LSB is suppressed for a driver slice. In the latter instance, the AND gate 406 in each driver slice may receive additional control signals that force the D signal 418 to the low signaling state even when the corresponding logic subcircuit 400 receives a version of the MSB or LSB that are both in the low signaling state.

Other combinations of logic gates may be used to implement different versions of the driver subcircuit 420, including versions of the driver subcircuit 420 that produce functionally equivalent control signals, and versions of the driver subcircuit 420 that can respond to additional inputs or provide different combinations of outputs. In some implementations, the control transistors 422, 424, 426A, 426B, 428A, 428B in the enabled driver slices receive the same control signals, or control signals generated by identically-configured driver subcircuits. In some implementations, the control transistors 422, 424, 426A, 426B, 428A, 428B in one or more enabled driver slices are gated or modified using additional control signals. For example, certain of the control transistors 422, 424, 426A, 426B, 428A, 428B that are turned on in a first enabled driver slice may be turned off in a second enabled driver slice based on signaling state of one or more additional control signals provided to the enabled driver slices.

In some implementations, the D signal 418 may be provided as the inverse of the A signal 412, whereby the gate of pullup transistor 422 may be configured to receive an inverted version (A_{N}) of the A signal 412. In these implementations, pulldown transistor 424 is turned on when LSB=MSB=0.

Certain pairs of the transistors 422, 424, 426A, 426B, 428A, 428B may be controlled by complementary versions of a control signal. In the illustrated example, pullup transistor 426A and pulldown transistor 426B may be referred to as a differentially controlled transistor pair. The gates of pullup transistor 426A and pulldown transistor 426B receive complementary versions of the B signal 414. Pullup transistor 428A and pulldown transistor 428B may be referred to as a differentially controlled transistor pair. The gates of pullup transistor 428A and pulldown transistor 428B receive complementary versions of the C signal 416.

In the illustrated logic subcircuit 400, the A signal 412, B signal 414, the C signal 416 and the D signal 418 are depicted as single-ended signals. The A signal 412, B signal 414, the C signal 416 and the D signal 418 are provided to differential conversion circuits 408a, 408b, 408c and 408d respectively to obtain complementary versions of the A signal 412, the B signal 414, the C signal 416 and the D signal 418. In some implementations, the logic subcircuit 400 is implemented using logic gates that are configured to output differential signals. In these latter implementations, the differential conversion circuits 408a and 408b may not be needed or used. The logic subcircuit 400 may be implemented using different types and/or combinations of logic gates.

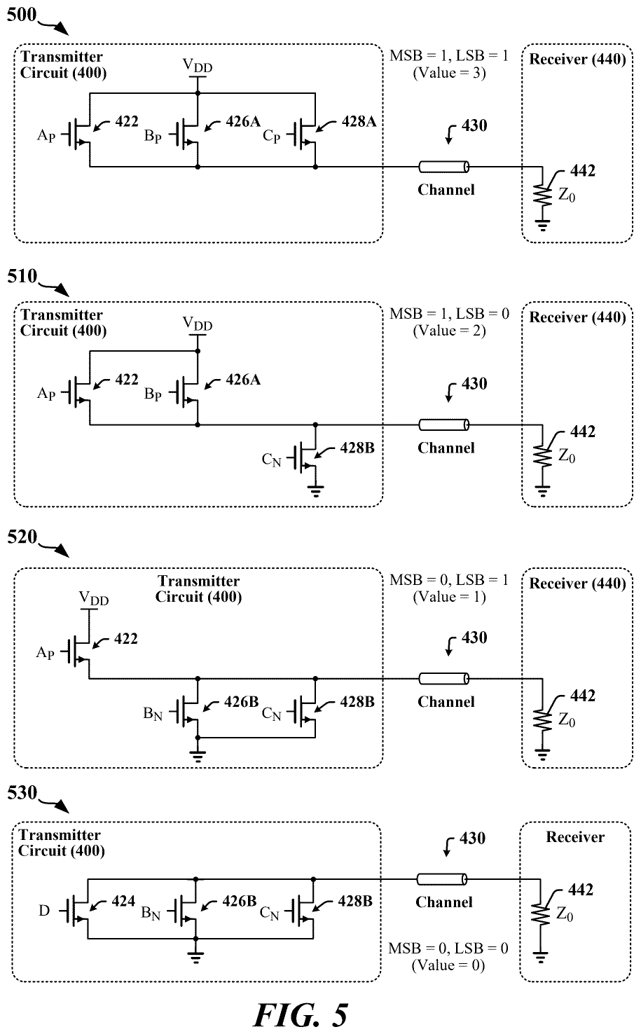

FIG. 5 illustrates configurations 500, 510, 520, 530 of the driver subcircuit 420 for each signaling state supported by a PAM-4 interface. The PAM-4 interface is used to encode two-bit numbers in each data transmission interval. In one example, the two-bit numbers are received in the two-bit datastream 216 output by the serializer 202 illustrated in FIG. 2. In each of the configurations 500, 510, 520, 530, any of the transistors 422, 424, 426A, 426B, 428A, 428B that are turned off or otherwise disabled are excluded from the corresponding drawing.

The first illustrated configuration 500 is in effect when a two-bit number with a value of ‘3’ is encoded by the PAM-4 interface. Both the MSB and LSB are in the high signaling state. The A signal 412 is driven to a high signaling state turning on transistor 422. The B signal 414 is defined by the MSB and is in the high signaling state, turning on transistor 426A and turning off transistor 426B. The C signal 416 is driven to the high signaling state turning on transistor 428A and turning off transistor 428B. The D signal 418 is in the low signaling state, turning off transistor 424. In this configuration 500, transistors 422, 426A and 428A are turned on.

The second illustrated configuration 510 is in effect when a two-bit number with a value of ‘2’ is encoded by the PAM-4 interface. The MSB is in the high signaling state and the LSB is in the low signaling state. The A signal 412 is driven to a high signaling state turning on transistor 422. The B signal 414 is defined by the MSB and is in the high signaling state, turning on transistor 426A and turning off transistor 426B. The C signal 416 is driven to the low signaling state turning off transistor 428A and turning on transistor 428B. The D signal 418 is in the low signaling state, turning off transistor 424. In this configuration 510, transistors 422, 426A and 428B are turned on.

The third illustrated configuration 520 is in effect when a two-bit number with a value of ‘1’ is encoded by the PAM-4 interface. The MSB is in the low signaling state and the LSB is in the high signaling state. The A signal 412 is driven to a high signaling state turning on transistor 422. The B signal 414 is defined by the MSB and is in the low signaling state, turning off transistor 426A and turning on transistor 426B. The C signal 416 is driven to the low signaling state turning off transistor 428A and turning on transistor 428B. The D signal 418 is in the low signaling state, turning off transistor 424. In this configuration 520, transistors 422, 426B and 428B are turned on.

The fourth illustrated configuration 530 is in effect when a two-bit number with a value of ‘0’ is encoded by the PAM-4 interface. Both the MSB and LSB are in the low signaling state. The A signal 412 is driven to a low signaling state turning off transistor 422. The B signal 414 is defined by the MSB and is in the low signaling state, turning off transistor 426A and turning on transistor 426B. The C signal 416 is driven to the low signaling state turning off transistor 428A and turning on transistor 428B. The D signal 418 is in the high signaling state, turning on transistor 424. In this configuration 520, transistors 424, 426B and 428B are turned on.

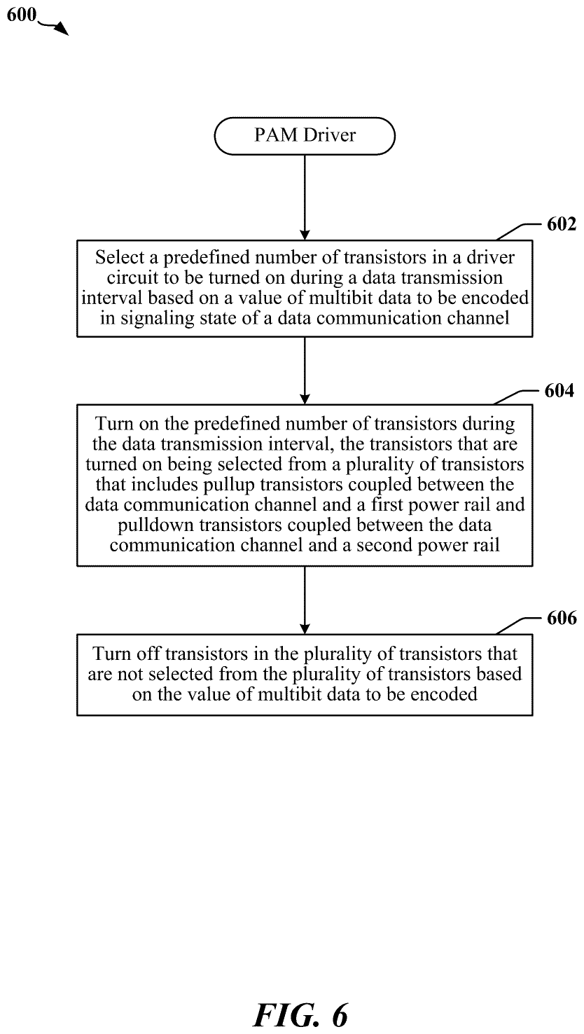

FIG. 6 is a flowchart 600 of a method for transmitting data using a driver circuit configured in accordance with certain aspects of this disclosure. The driver circuit may be provided in a transmitting device and may correspond in some respects to the transmitter circuit 200 illustrated in FIG. 2. In one example, the method may be used to operate the driver subcircuit 420 illustrated in FIG. 4. According to certain aspects of this disclosure, the method may be used to operate a driver subcircuit that includes pullup transistors coupled between an output of the driver circuit and a first power rail, and pulldown transistors that are coupled between the output of the driver circuit and a second power rail. Certain control signals used to operate the driver circuit may be generated by combinational logic, which may be configured in accordance with the logic subcircuit 400 illustrated in FIG. 4.

At block 602 in the illustrated method, a predefined number of transistors in a driver circuit are selected to be turned on during a data transmission interval. Selection may be accomplished using a value of multibit data to be encoded in signaling state of a data communication channel. At block 604 in the illustrated method, the predefined number of transistors may be turned on during the data transmission interval. The transistors that are turned on may be selected from a plurality of transistors that includes pullup transistors coupled between the data communication channel and a first power rail and pulldown transistors coupled between the data communication channel and a second power rail. The output of the driver circuit may be coupled to the data communication channel. At block 606 in the illustrated method, transistors in the plurality of transistors may be turned off during the data transmission interval. Transistors that are not selected from the plurality of transistors based on the value of multibit data to be encoded are turned off.

In some implementations, the multibit data is to be encoded using PAM. In one example, PAM-4 modulation is used to encode two-bit elements of the multibit data. Each two-bit element may be configured as a two-bit number having an MSB and an LSB. The two-bit number may be received in a serial datastream. In one example, three transistors are turned on during each data transmission interval. The three transistors may include three pullup transistors when the multibit data to be encoded has a first value. The three transistors may include two pullup transistors and one pulldown transistors when the multibit data to be encoded has a second value. The three transistors may include one pullup transistors and two pulldown transistors when the multibit data to be encoded has a third value. The three transistors may include three pulldown transistors when the multibit data to be encoded has a fourth value.

In some implementations, four different signaling states are defined for the data communication channel. In one example, a combination of pullup transistors and pulldown transistors turned on during each data transmission interval produces voltage levels in the data communication channel that correspond to one of the four different signaling states.

In certain implementations, each transistor in the plurality of transistors is configured to contribute a same nominal impedance to an output of the driver circuit when turned on. In certain implementations, differential control signals are used to control pairs of transistors in the plurality of transistors. In certain implementations, the pullup transistors and the pulldown transistors comprise N-type metal-oxide-semiconductor transistors.

In certain implementations, a driver circuit has a logic circuit and at least one driver subcircuit. A driver subcircuit includes pullup transistors that are coupled between an output of the driver circuit and a first power rail and pulldown transistors that are coupled between the output of the driver circuit and a second power rail. The logic circuit may include combinational logic and may be configured to turn on a predefined number of transistors during each data transmission interval. The duration of the data transmission interval may be configured for an associated data communication channel. The transistors that are turned on may be selected during each data transmission interval based on a value of multibit data to be encoded in signaling state of the data communication channel. The logic circuit may be further configured to turn off transistors in the plurality of transistors that are not selected from the plurality of transistors based on the value of multibit data to be encoded.

In some implementations, the multibit data is to be encoded using PAM. In one example, PAM-4 modulation is used to encode two-bit elements of the multibit data. Each two-bit element may be configured as a two-bit number having an MSB and an LSB. The two-bit number may be received in a serial datastream. In one example, the logic circuit is configured to turn on three transistors during each data transmission interval. The three transistors may include three pullup transistors when the multibit data to be encoded has a first value. The three transistors may include two pullup transistors and one pulldown transistors when the multibit data to be encoded has a second value. The three transistors may include one pullup transistors and two pulldown transistors when the multibit data to be encoded has a third value. The three transistors may include three pulldown transistors when the multibit data to be encoded has a fourth value.

In some implementations, four different signaling states are defined for the data communication channel. In one example, a combination of pullup transistors and pulldown transistors turned on during each data transmission interval produces voltage levels in the data communication channel that correspond to one of the four different signaling states.

In certain implementations, each transistor in the plurality of transistors is configured to contribute a same nominal impedance to an output of the driver circuit when turned on. In certain implementations, differential control signals are used to control pairs of transistors in the plurality of transistors. In certain implementations, the pullup transistors and the pulldown transistors comprise N-type metal-oxide-semiconductor transistors.

Some implementation examples are described in the following numbered clauses:
1. A driver circuit, comprising: a plurality of transistors that includes pullup transistors that are coupled between an output of the driver circuit and a first power rail and pulldown transistors that are coupled between the output of the driver circuit and a second power rail; and a logic circuit configured to: turn on a predefined number of transistors during each data transmission interval configured for a data communication channel, the transistors that are turned on being selected during the each data transmission interval from the plurality of transistors based on a value of multibit data to be encoded in signaling state of the data communication channel, and turn off transistors in the plurality of transistors that are not selected from the plurality of transistors based on the value of multibit data to be encoded.
2. The driver circuit as described in clause 1, wherein the multibit data is to be encoded using pulse-amplitude modulation.
3. The driver circuit as described in clause 2, wherein the logic circuit is configured to turn on three transistors during each data transmission interval, the three transistors including: three pullup transistors when the multibit data to be encoded has a first value; two pullup transistors and one pulldown transistors when the multibit data to be encoded has a second value; one pullup transistors and two pulldown transistors when the multibit data to be encoded has a third value; and three pulldown transistors when the multibit data to be encoded has a fourth value.
4. The driver circuit as described in any of clauses 1-3, wherein four different signaling states are defined for the data communication channel.
5. The driver circuit as described in clause 4, wherein a combination of pullup transistors and pulldown transistors turned on during each data transmission interval produce voltage levels in the data communication channel that correspond to one of the four different signaling states.
6. The driver circuit as described in any of clauses 1-5, wherein each transistor in the plurality of transistors is configured to contribute a same nominal impedance to the output of the driver circuit when turned on.
7. The driver circuit as described in any of clauses 1-6, wherein the plurality of transistors includes differentially controlled transistor pairs.
8. The driver circuit as described in any of clauses 1-7, wherein the pullup transistors and the pulldown transistors comprise N-type metal-oxide-semiconductor transistors.
9. The driver circuit as described in any of clauses 1-8, wherein the multibit data to be encoded comprises a two-bit number.
10. The driver circuit as described in clause 9, wherein the two-bit number is received in a serial datastream.
11. A method for transmitting data, comprising: selecting a predefined number of transistors in a driver circuit to be turned on during a data transmission interval based on a value of multibit data to be encoded in signaling state of a data communication channel; turning on the predefined number of transistors during the data transmission interval, the transistors that are turned on being selected from a plurality of transistors that includes pullup transistors coupled between the data communication channel and a first power rail and pulldown transistors coupled between the data communication channel and a second power rail; and turning off transistors in the plurality of transistors that are not selected from the plurality of transistors based on the value of multibit data to be encoded.
12. The method as described in clause 11, wherein the multibit data is to be encoded using pulse-amplitude modulation.
13. The method as described in clause 12, further comprising turning on three transistors during each data transmission interval, the three transistors including: three pullup transistors when the multibit data to be encoded has a first value; two pullup transistors and one pulldown transistors when the multibit data to be encoded has a second value; one pullup transistors and two pulldown transistors when the multibit data to be encoded has a third value; and three pulldown transistors when the multibit data to be encoded has a fourth value.
14. The method as described in any of clauses 11-13, wherein four different signaling states are defined for the data communication channel.
15. The method as described in clause 14, wherein a combination of pullup transistors and pulldown transistors turned on during each data transmission interval produce voltage levels in the data communication channel that correspond to one of the four different signaling states.
16. The method as described in any of clauses 11-15, wherein each transistor in the plurality of transistors is configured to contribute a same nominal impedance to an output of the driver circuit when turned on.
17. The method as described in any of clauses 11-16, further comprising: using differential control signals control pairs of transistors in the plurality of transistors.
18. The method as described in any of clauses 11-17, wherein the pullup transistors and the pulldown transistors comprise N-type metal-oxide-semiconductor transistors.
19. The method as described in any of clauses 11-18, wherein the multibit data to be encoded comprises a two-bit number.
20. The method as described in clause 19, further comprising: receiving the two-bit number in a serial datastream.

It is understood that the specific order or hierarchy of steps in the processes disclosed is an illustration of exemplary approaches. Based upon design preferences, it is understood that the specific order or hierarchy of steps in the processes may be rearranged. Further, some steps may be combined or omitted. The accompanying method claims present elements of the various steps in a sample order, and are not meant to be limited to the specific order or hierarchy presented.

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein, but is to be accorded the full scope consistent with the language claims, wherein reference to an element in the singular is not intended to mean “one and only one” unless specifically so stated, but rather “one or more.” Unless specifically stated otherwise, the term “some” refers to one or more. All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed as a means plus function unless the element is expressly recited using the phrase “means for.”

What is claimed is:

1. A driver circuit, comprising:
a plurality of transistors that includes pullup transistors that are coupled between an output of the driver circuit and a first power rail and pulldown transistors that are coupled between the output of the driver circuit and a second power rail; and
a logic circuit configured to:
turn on a predefined number of transistors during each data transmission interval configured for a data communication channel, the transistors that are turned on being selected during the each data transmission interval from the plurality of transistors based on a value of multibit data to be encoded in signaling state of the data communication channel, and
turn off transistors in the plurality of transistors that are not selected from the plurality of transistors based on the value of multibit data to be encoded.

2. The driver circuit of claim 1, wherein the multibit data is to be encoded using pulse-amplitude modulation.

3. The driver circuit of claim 2, wherein the logic circuit is configured to turn on three transistors during each data transmission interval, the three transistors including:
three pullup transistors when the multibit data to be encoded has a first value;
two pullup transistors and one pulldown transistors when the multibit data to be encoded has a second value;
one pullup transistors and two pulldown transistors when the multibit data to be encoded has a third value; and
three pulldown transistors when the multibit data to be encoded has a fourth value.

4. The driver circuit of claim 1, wherein four different signaling states are defined for the data communication channel.

5. The driver circuit of claim 4, wherein a combination of pullup transistors and pulldown transistors turned on during each data transmission interval produce voltage levels in the data communication channel that correspond to one of the four different signaling states.

6. The driver circuit of claim 1, wherein each transistor in the plurality of transistors is configured to contribute a same nominal impedance to the output of the driver circuit when turned on.

7. The driver circuit of claim 1, wherein the plurality of transistors includes differentially controlled transistor pairs.

8. The driver circuit of claim 1, wherein the pullup transistors and the pulldown transistors comprise N-type metal-oxide-semiconductor transistors.

9. The driver circuit of claim 1, wherein the multibit data to be encoded comprises a two-bit number.

10. The driver circuit of claim 9, wherein the two-bit number is received in a serial datastream.

11. A method for transmitting data, comprising:
selecting a predefined number of transistors in a driver circuit to be turned on during a data transmission interval based on a value of multibit data to be encoded in signaling state of a data communication channel;
turning on the predefined number of transistors during the data transmission interval, the transistors that are turned on being selected from a plurality of transistors that includes pullup transistors coupled between the data communication channel and a first power rail and pulldown transistors coupled between the data communication channel and a second power rail; and
turning off transistors in the plurality of transistors that are not selected from the plurality of transistors based on the value of multibit data to be encoded.

12. The method of claim 11, wherein the multibit data is to be encoded using pulse-amplitude modulation.

13. The method of claim 12, further comprising turning on three transistors during each data transmission interval, the three transistors including:
three pullup transistors when the multibit data to be encoded has a first value;
two pullup transistors and one pulldown transistors when the multibit data to be encoded has a second value;
one pullup transistors and two pulldown transistors when the multibit data to be encoded has a third value; and
three pulldown transistors when the multibit data to be encoded has a fourth value.

14. The method of claim 11, wherein four different signaling states are defined for the data communication channel.

15. The method of claim 14, wherein a combination of pullup transistors and pulldown transistors turned on during each data transmission interval produce voltage levels in the data communication channel that correspond to one of the four different signaling states.

16. The method of claim 11, wherein each transistor in the plurality of transistors is configured to contribute a same nominal impedance to an output of the driver circuit when turned on.

17. The method of claim 11, further comprising:
using differential control signals control pairs of transistors in the plurality of transistors.

18. The method of claim 11, wherein the pullup transistors and the pulldown transistors comprise N-type metal-oxide-semiconductor transistors.

19. The method of claim 11, wherein the multibit data to be encoded comprises a two-bit number.

20. The method of claim 19, further comprising:
receiving the two-bit number in a serial datastream.
